(19) United States
(12) Patent Application Publication
(10) Pub. No.: US 2007/0096966 A1
(43) Pub. Date: May 3, 2007

(54) Data driver and organic light emitting display device using the same

(76) Inventors: Do Youb Kim, Seoul (KR); Yong Sung Park, Seoul (KR)

Correspondence Address: CHRISTIE, PARKER & HALE, LLP, PO BOX 7068, PASADENA, CA, 91109-7068, US

(21) Appl. No.: 11/544,131

(22) Filed: Oct. 5, 2006

(30) Foreign Application Priority Data
Nov. 3, 2005 (KR) 10-2005-105123

(51) Int. Cl. H03M 1/66

(52) U.S. Cl. 341/144

(57) ABSTRACT

A data driver and an organic light emitting display device using the same, in which power consumption and a layout area thereof are reduced. The data driver includes: a shift registering part adapted to supply sampling signals; a sampling latching part including sampling latches adapted to store data in response to the sampling signals; and a holding latching part including holding latches adapted to receive the data stored in the sampling latches in response to an externally supplied source output enable signal. Each of the sampling latches includes sampling bit storages. Each of the sampling bit storages includes: a first input unit adapted to receive a certain bit of the data; a first capacitor adapted to store voltage corresponding to a logic signal of the certain bit supplied from the first input unit; and a first inverter adapted to inverse the logic signal stored in the first capacitor.

### CROSS-REFERENCE TO RELATED APPLICATION

This application claims priority to and the benefit of Korean Patent Application No. 10-2005-0105123, filed on Nov. 3, 2005, in the Korean Intellectual Property Office, the entire content of which is incorporated herein by reference.

### BACKGROUND

1. Field of the Invention

The present invention relates to a data driver and an organic light emitting display device using the same, and more particularly, to a data driver and an organic light emitting display device using the same, in which power consumption and a layout area thereof are reduced.

2. Discussion of Related Art

An organic light emitting display device is a flat panel display device that employs organic light emitting diodes capable of emitting light based on electron-hole recombination, thereby displaying an image. The organic light emitting display device has a relatively fast response time and a relatively low power consumption. The light emitting display device includes a driving thin film transistor (hereinafter, referred to as “TFT”) provided in each pixel of the organic light emitting display device, and uses the driving transistor to supply a current corresponding to a data signal to a corresponding one of the organic light emitting diodes, thereby allowing the corresponding one of the organic light emitting diodes to emit light.

The organic light emitting display device generates data signals based on external data, and transmits the data signals to pixels of the organic light emitting display device, thereby displaying an image with desired brightness. To convert the external data into the data signals, the organic light emitting display device employs a data driver.

### SUMMARY OF THE INVENTION

It is an aspect of the present invention to provide a data driver and an organic light emitting display device using the same, in which power consumption and a layout area thereof are reduced.

In an exemplary embodiment of the present invention, a data driver includes: a shift registering part adapted to supply sampling signals; a sampling latching part including sampling latches adapted to store data in response to the sampling signals; and a holding latching part including holding latches adapted to receive the data stored in the sampling latches in response to an externally supplied source output enable signal. Each of the sampling latches includes sampling bit storages. Each of the sampling bit storages includes: a first input unit adapted to receive a certain bit of the data; a first capacitor adapted to store voltage corresponding to a logic signal of the certain bit supplied from the first input unit; and a first inverter adapted to inverse the logic signal stored in the first capacitor.

According to an embodiment of the invention, the sampling bit storages include k sampling bit storages to store data of k bits (k is a natural number).

According to an embodiment of the invention, the first input unit includes: a first transistor adapted to turn on when the sampling signal is supplied and to supply the certain bit to the first capacitor; and a second transistor adapted to turn on when an initialization signal is supplied from the outside and to supply a certain voltage to initialize the first capacitor.

According to an embodiment of the invention, the first input unit includes a first transistor and a second transistor. The first transistor and the second transistor are connected in a transmission gate form and supply the certain bit to the first capacitor when the sampling signal and an inversed sampling signal are supplied.

According to another embodiment of the present invention, an organic light emitting display device includes: a scan driver adapted to drive scan lines; a data driver adapted to supply a data signal to data lines and including a plurality of sampling bit storages and a plurality of holding bit storages adapted to store a bit of the data; and a display region including a plurality of pixels connected with the scan lines and the data lines and adapted to emit light corresponding to the data signal. Each of the sampling bit storages includes: a first input unit adapted to receive a certain bit of the data signal; a first capacitor adapted to store voltage corresponding to a logic signal of the certain bit supplied from the first input unit; and a first inverter adapted to inverse the logic signal stored in the first capacitor.

According to an embodiment of the invention, the first input unit includes: a first transistor adapted to turn on when a sampling signal is supplied from a shift register provided in the data driver and to supply the certain bit to the first capacitor; and a second transistor adapted to turn on when an initialization signal is supplied from an external source and to supply a certain voltage to initialize the first capacitor.

According to an embodiment of the invention, the first input unit includes a first transistor and a second transistor which are connected in a transmission gate form and supply the certain bit to the first capacitor when a sampling signal and an inversed sampling signal are supplied from a shift register provided in the data driver.

According to an embodiment of the invention, each of the holding bit storages includes: a second input unit adapted to receive the certain bit from the sampling bit storage connected thereto; a second capacitor adapted to store voltage corresponding to a logic signal of the certain bit supplied from the second input unit; and a second inverter adapted to inverse the logic signal stored in the second capacitor.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 illustrates a conventional sampling latching part and a conventional holding latching part;

FIG. 2 illustrates a conventional sampling bit storage and a conventional holding bit storage;

FIG. 3 is a circuit diagram of an internal configuration of an inverter of FIG. 2;

FIG. 4 illustrates an organic light emitting display device according to an embodiment of the present invention;

FIG. 5 illustrates a data driving circuit of FIG. 4;

FIG. 6 illustrates a sampling bit storage and a holding bit storage according to an embodiment of the present invention;

FIG. 7 shows waveforms of sampling signals, source output enable signals, and an initialization signal; and

FIG. 8 illustrates a sampling bit storage and a holding bit storage according to another embodiment of the present invention.

### DETAILED DESCRIPTION

In the following detailed description, certain exemplary embodiments of the present invention are shown and described, by way of illustration. As those skilled in the art would recognize, the described exemplary embodiments may be modified in various ways, all without departing from the spirit or scope of the present invention. Accordingly, the drawings and description are to be regarded as illustrative in nature, rather than restrictive.

FIG. 1 schematically illustrates a sampling latching part and a holding. latching part of a conventional data driver.

Referring to FIG. 1, a conventional sampling latching part 10 stores data corresponding to a sampling signal supplied in sequence from a shift register (not shown). In this case, the sampling latching part 10 includes i sampling latches 101 though 10i to store i data Data (i is a natural number). Further, each of the sampling latches 101 through 10i is provided with a sampling bit storage for storing a digital value of the data Data. Here, each of the sampling bit storage has a capacity for storing 1 bit of the data Data. Therefore, when the data Data is of k bits (k is a natural number), each of the sampling latches is provided with k sampling bit storages.

The holding latching part 20 receives and stores the data Data from the sampling latching part 10 in response to a source output enable signal SOE supplied from an external source. Further, the holding latching part 20 supplies the stored data Data to a level shifter (not shown). Like the sampling latching part 10, the holding latching part 20 includes i holding latches 201 though 20i. Also, each of the holding latches 201 through 20i is provided with k holding bit storages.

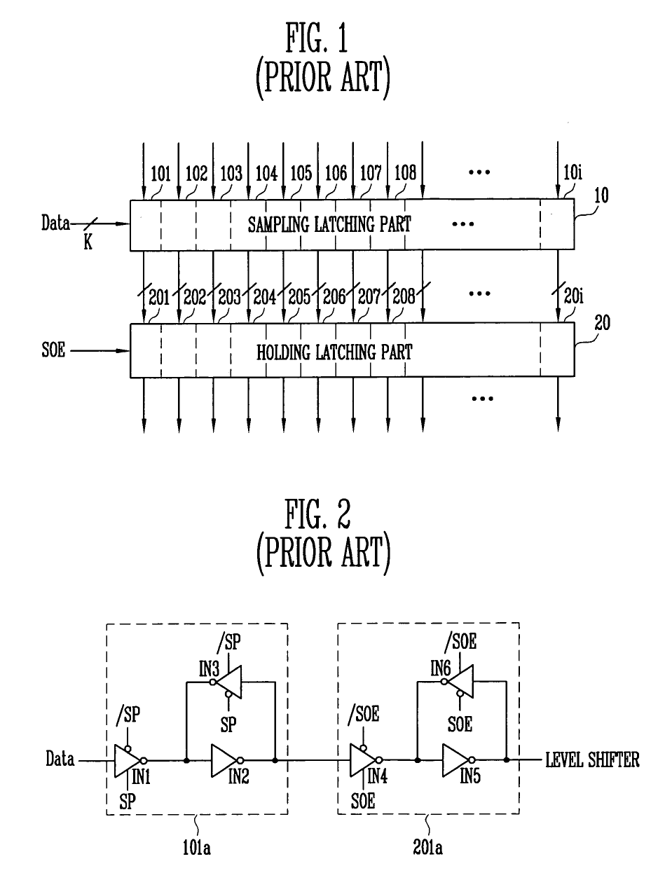

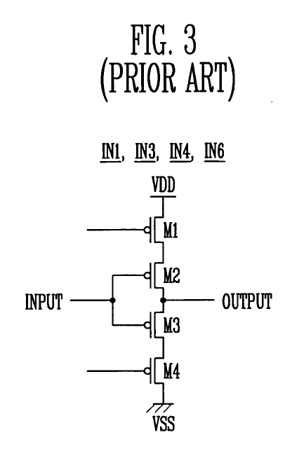

FIG. 2 is a circuit diagram showing a conventional sampling bit storage and a conventional holding bit storage.

Referring to FIG. 2, each of the sampling latches 101 through 10i includes a plurality of sampling bit storages 101a. Each of the sampling bit storages 101a is adapted to store 1 bit of the data Data. For this, each sampling bit storage 101a includes a first inverter IN1, a second inverter IN2 and a third inverter IN3.

The first inverter IN1 inverts a certain bit of the data Data in response to a sampling signal SP and an inversed sampling signal /Sp, and supplies inversed data Data to the second inverter IN2. For example, when a logic signal of “0” is input at the certain bit, the first inverter IN1 inverses the logic signal of “0” into a logic signal of “1” and supplies the logic signal of “1” to the second inverter IN2.

The second inverter IN2 inverses the logic signal from the first inverter IN1. For example, the second inverter IN2 inverses the logic signal of “1” into the logic signal of “0” when receiving the logic signal of “1” from the first inverter IN1.

The third inverter IN3 feeds the logic signal output from the second inverter IN2 back to the second inverter IN2 in response to the sampling signal SP and the inversed sampling signal /SP. That is, the third inverter IN3 allows the second inverter IN2 to stably maintain the output signal.

The holding bit storage 201a provided in each of the holding latches 201 through 20 temporarily stores 1 bit of the data Data supplied from the sampling bit storage 101a, and supplies 1 bit of the stored data Data to the level shifter. For this, the holding bit storage 201a includes a fourth inverter IN4, a fifth inverter IN5 and a sixth inverter IN6.

The fourth inverter IN4 inverses 1 bit of the data Data supplied from the sampling bit storage 101a in response to a source output enable signal SOE and an inversed source output enable signal /SOE, and supplies it to the fifth inverter IN5. For example, when the logic signal of “0” is output from the sampling bit storage 101a, the fourth inverter IN4 inverses the logic signal of “0” into the logic signal of “1”, thereby supplying the logic signal of “1” to the fifth inverter IN5.

The fifth inverter IN5 inverses the logic signal output from the fourth inverter IN4, and outputs the inversed logic signal. For example, the fifth inverter IN5 receives the logic signal of “1” and outputs the logic signal of “0”.

The sixth inverter N6 feeds the logic signal output from the fifth inverter IN5 back to the fifth inverter IN5 in response to the source output enable signal SOE and the inversed source output enable signal /SOE. That is, the sixth inverter IN6 allows the fifth inverter IN5 to stably maintain the output signal.

Substantially, as shown in FIG. 2, each sampling latches 101 through 10i and each holding latches 201 through 20i include k sampling bit storages 101a and k holding bit storages 201a to store data of k bits, respectively. Each sampling bit storage 101a and each holding bit storage 201a repeat the foregoing operations to thereby receive the data Data from the external source and supply the received data Data to the level shifter.

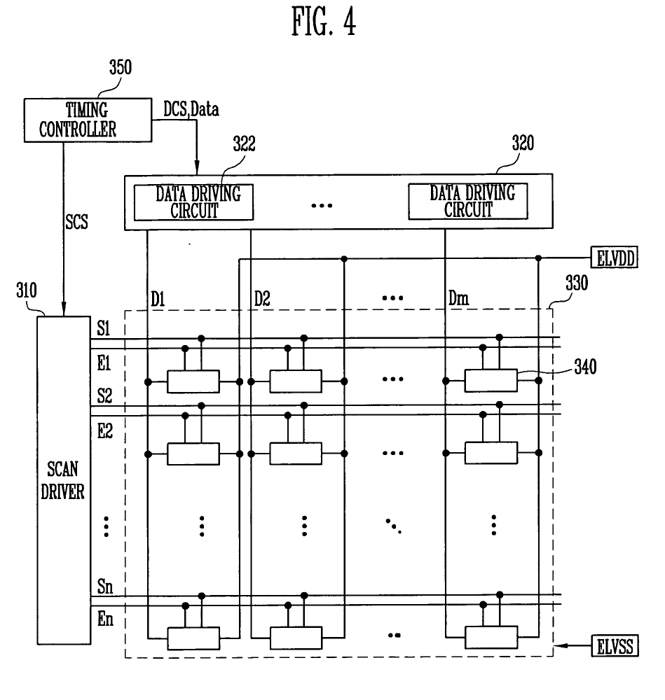

However, the conventional sampling bit storage 101a and the conventional holding bit storage 201a occupy a large layout area, so that it is difficult to mount them on a panel. Substantially, the first inverter IN1, the third inverter IN3, the fourth inverter IN4, and the sixth inverter IN6 provided in the sampling bit storage 101a and the holding bit storage 201a are implemented by four transistors M1, M2, M3, and M4 as shown in FIG. 3, and ten or more transistors are needed to make the sampling bit storage 101a and the holding bit storage 201a. Thus, the layout area of the conventional sampling bit storage 101a and the conventional holding bit storage 201a is large. Further, the conventional sampling bit storage 101a and the conventional holding bit storage 201a employ the third inverter IN3 and the sixth inverter IN6 to feed back the output logic signals, respectively. Thus, additional powers are consumed as the output logic signals are fed back to the conventional sampling bit storage 101a and the conventional holding bit storage 201 a, respectively.

FIG. 4 illustrates a light emitting display device according to an embodiment of the present invention.

Referring to FIG. 4, a light emitting display device according to an embodiment of the present invention includes a display region 330 corresponding to a plurality of pixels 340 formed in regions defined by where a plurality of scan lines S1 through Sn cross (or intersect) a plurality of data lines D1 through Dm; a scan driver 310 to drive the scan lines S1 through Sn; a data driver 320 to drive the data lines D1 through Dm; and a timing controller 350 to control the scan driver 310 and the data driver 320.

The scan driver 310 generates scan signals in response to scan control signals SCS from the timing controller 350, and supplies (or sequentially supplies) the scan signals to the scan lines S1 through Sn. Further, the scan driver 310 generates emission control signals in response to the scan control signals SCS, and supplies (or sequentially supplies) the emission control signals to a plurality of emission control lines E1 through En.

The data driver 320 generates data signals in response to data control signals DCS from the timing controller 350, and supplies the data signals to the data lines D1 through Dm. For this, the data driver 320 includes at least one data driving (or data integrated) circuit (or a plurality of data driving circuits) 322. The data driving circuit 322 converts (or changes) data Data supplied from an external source into the data signals, and supplies the data signals to the data lines D1 through Dm. Configurations of the data driving circuit 322 will be described in more detail below.

The timing controller 350 generates the data control signal DCS and the scan control signal SCS in response to synchronization (or synchronous) signals supplied from an external source. The data control signal DCS and the scan control signal SCS generated by the timing controller 350 are supplied to the data driver 320 and the scan driver 310, respectively. Further, the timing controller 350 rearranges the data Data supplied from the external source, and supplies it to the data driver 320.

The display region 330 receives a first power of a first power source ELVDD and a second power of a second power source ELVSS. The first power of the first power source ELVDD and the second power of the second power source ELVSS supplied to the display region 330 are applied to the plurality of pixels 340. After receiving the first power of the first power source ELVDD and the second power of the second power source ELVSS, the pixels 340 display an image corresponding to the data signals.

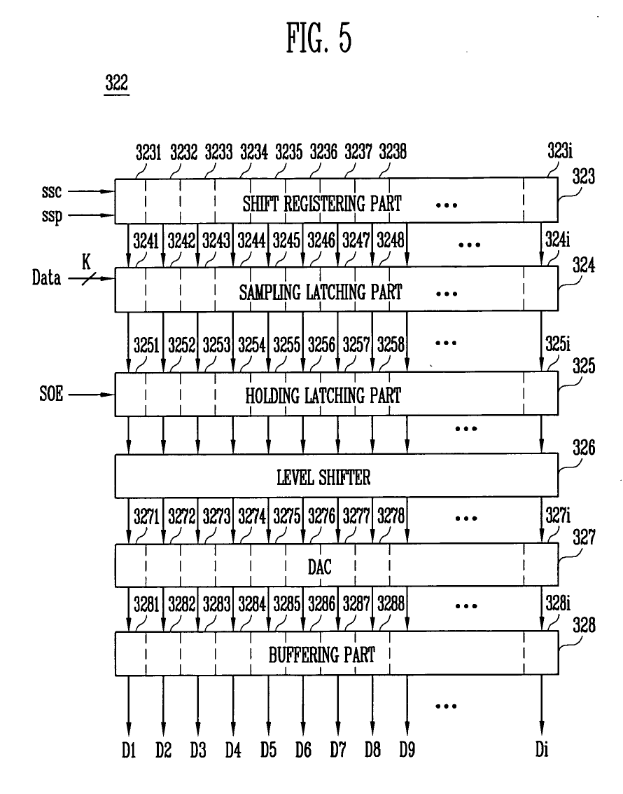

FIG. 5 is a schematic block diagram of the data driving circuit 322 shown in FIG. 4. For convenience purposes, it is assumed that the data driving circuit 322 has i channels.

Referring to FIG. 5, the data driving circuit 322 includes a shift registering part 323 to generate (or sequentially generate) first sampling signals; a sampling latching part 324 to store (or sequentially store) the data Data in response to the first sampling signals; a holding latching part 325 to temporarily store (or hold) the data Data stored in the sampling latching part 324 and to supply the stored data Data to a level shifter 326; a digital analog converter (DAC) 327 to generate data signals corresponding to digital values of the data Data; and a buffering part 328 to supply the data signals to the data lines D1 through Dm.

The shift registering part 323 receives a source shift clock ssc and a source start pulse ssp from the timing controller 350. After receiving the source shift clock ssc and the source start pulse ssp, the shift registering part 323 shifts the source start pulse ssp in correspondence to the source shift clock ssc, and generates (or sequentially generates) i sampling signals. For this, the shift registering part 323 includes i shift registers 3231 through 323i.

The sampling latching part 324 stores (or sequentially stores) the data Data corresponding to the sampling signal supplied (or sequentially supplied) from the shift registering part 323. For this, the sampling latching part 324 includes i sampling latches 3241 through 324i to store i data. Further, each of the sampling latches 3241 through 324i includes a sampling bit storage for storing a digital value of the data Data. Here, each sampling bit storage has a capacity to store 1 bit of the data Data. Therefore, when the data Data is of k bits, each of the sampling latches 3241 through 324i includes k sampling bit storages.

The holding latching part 325 receives and stores the data Data from the sampling latching part 324 in response to the source output enable signal SOE transmitted from the timing controller 350, and outputs the stored data Data to the level shifter 326. For this, the holding latching part 325 includes i holding latches 3251 through 325i. Further, each of the holding latches 3251 through 325i includes k holding bit storages, and each of the k holding bit storages is capable of storing 1 bit.

The level shifter 326 raises (or boosts) a voltage level of the data Data output from the holding latching part 325, and outputs the shifted (or boosted) data Data to the DAC 327. By contrast, if external circuit components for providing a high voltage level are used to supply the data Data having the high voltage level, production cost increases because the external circuit components that can supply the high voltage level are expensive. Therefore, by using the level shifter 326, the data Data having a low voltage level is first externally supplied by the data driver 320, and then the data Data having the low voltage level is boosted by the level shifter 326 to have the high level. However, the present invention is not thereby limited, and in an alternative embodiment of the present invention, the level shifter 326 may be omitted. In this alternative embodiment of the present invention, the holding latching part 325 is directly connected to the DAC 327.

The DAC 327 generates a data signal corresponding to a digital value (or gradation value) of the data Data, and supplies the generated data signal to the buffering part 328. Substantially, the DAC 327 generates a voltage and/or a current as the data signal corresponding to the digital value of the data Data.

The buffering part 328 supplies the data signal from the DAC 327 to the data lines D1 through Di. Alternatively, the buffering part 328 may be removed such that the data signal is directly supplied from the DAC 327 to the data lines D1 through Di.

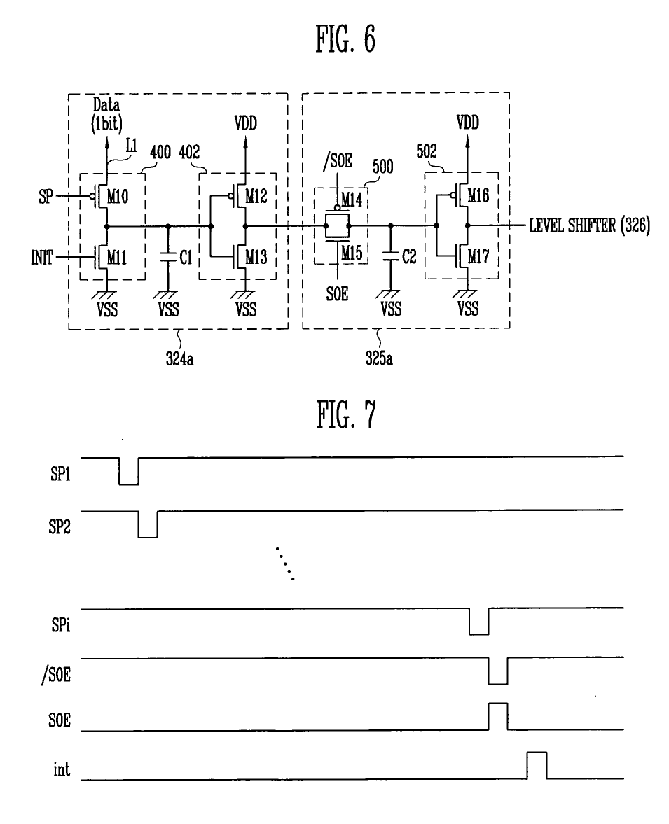

FIG. 6 illustrates a sampling bit storage and a holding bit storage according to an embodiment of the present invention.

Referring to FIG. 6, each of the sampling latches. 3241 through 324i includes k sampling bit storages 324a. Each of the sampling bit storages 324a is adapted to store 1 bit of the data Data. For this, each sampling bit storage 324a includes a first input unit 400, a first capacitor C1, and a first inverter 402.

The first input unit 400 supplies 1 bit of the data Data to the first capacitor C1. The 1 bit of the data Data is received by the first capacitor C1 when the sampling signal SP is supplied. For this, the first input unit 400 includes a first transistor M10 and a second transistor M11 between a data supplying line L1 and a second voltage VSS.

The first transistor M10 has a first electrode connected to the data supplying line L1, and a second electrode connected to a second electrode of the second transistor M11. The first transistor M10 is implemented with a p-type metal oxide semiconductor (PMOS), and turned on when the sampling signal SP is supplied, thereby supplying 1 bit of the data Data from the data supplying line L1 to the first capacitor C1.

The second transistor M11 has a first electrode connected to the second voltage VSS, and the second electrode connected to the second electrode of the first transistor M10. The second transistor M11 is implemented with an n-type metal oxide semiconductor (NMOS), and turned on when an initialization signal INIT is supplied, thereby supplying the second voltage VSS to the first capacitor C1.

The first capacitor C1 is charged with a voltage corresponding to 1 bit of the data Data supplied from the first input unit 400. For example, the first capacitor C1 is charged with a voltage corresponding to a logic signal of “0” or a logic signal of “1” supplied from the first input unit 400. Then, the first capacitor C1 is initialized when the second voltage VSS is applied to the first input unit 400.

The first inverter 402 inverses the voltage of the logic signal charged in the first capacitor C1. For example, the first inverter 402 outputs the logic signal of “1” when the first capacitor C1 is charged with a voltage corresponding to the logic signal of “0”. On the other hand, the first inverter 402 outputs the logic signal of “0” when the first capacitor C1 is charged with a voltage corresponding to the logic signal of “1”. For this, the first inverter 402 includes a third transistor M12 implemented with a PMOS and a fourth transistor M13 implemented with an NMOS, which are connected between a first voltage VDD and the second voltage VSS. Here, the first voltage VDD is higher than the second voltage VSS.

Each of the holding latches 3251 through 325i includes k holding bit storages 325a. Each of the holding bit storages 325a is adapted to store 1 bit of the data Data. For this, the holding bit storage 325a includes a second input unit, a second capacitor C2 and a second inverter 502.

The second input unit 500 supplies 1 bit of the data Data from the sampling bit storage 324a to the second capacitor C2. The 1 bit of the data Data is received by the second capacitor C2 when the second input unit 500 receives the source output enable signal SOE and the inversed source output enable signal /SOE. For this, the second input unit 500 includes a fifth transistor M14 and a sixth transistor M15, which are connected in a transmission gate form.

The second capacitor C2 is charged with a voltage corresponding to 1 bit of the data Data supplied from the second input unit 500. For example, the second capacitor C2 is charged with a voltage corresponding to a logic signal of “0” or a logic signal of “1” supplied from the second input unit 500.

The second inverter 502 inverses the voltage of the logic signal charged in the second capacitor C2. For example, the second inverter 502 outputs the logic signal of “1” when the second capacitor C2 is charged with a voltage corresponding to the logic signal of “0”. On the other hand, the second inverter 502 outputs the logic signal of “0” when the second capacitor C2 is charged with a voltage corresponding to the logic signal of “1”. The second inverter 502 includes a seventh transistor M16 implemented with a PMOS and an eighth transistor M17 implemented with an NMOS, which are connected between the first voltage VDD and the second voltage VSS.

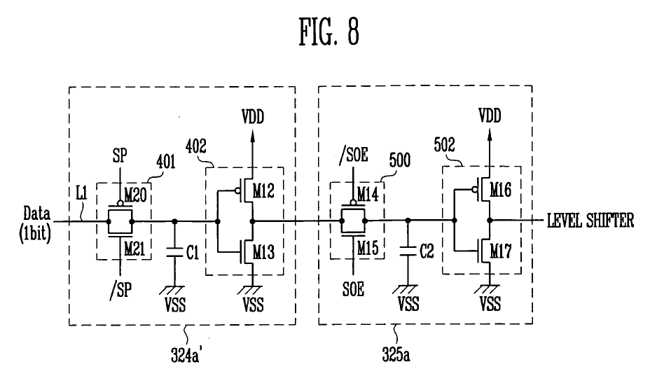

FIG. 7 shows waveforms of sampling signals, source output enable signals, and an initialization signal.

Referring to FIGS. 6 and 7, the sampling signals SP1 through SPi are supplied (or sequentially supplied) from the shift registering part 323.

The first transistor M10 of the first input unit 400 is turned on when it receives the sampling signal SP (i.e., the low level signal). As the first transistor M10 is turned on, 1 bit of the data Data being supplied to the data supplying line L1 is supplied to the first capacitor C1. At this time, the first capacitor C1 is charged with the voltage corresponding to the bit logic signal of the data Data supplied from the first transistor M10. For example, the first capacitor C1 is charged with a voltage corresponding to the logic signal of “1” when receiving the logic signal of “1” from the first transistor M10.

After charging the first capacitor C1 with the voltage corresponding to the logic signal of “1”, the first transistor M10 is turned off. At this time, the first inverter 402 inverses the logic signal corresponding to the voltage stored in the first capacitor C1. For example, when the first capacitor C1 is charged with the voltage corresponding to the logic signal of “1”, the fourth transistor M13 is turned on, thereby outputting the logic signal of “0”.

That is, substantially, the k sampling bit storages 324a included in each of sampling latches 3241 through 324i output the voltage corresponding to the logic signal of “1” or “0” via the foregoing processes when receiving the sampling signals SP1 through SPi.

Then, the holding latching part 325 receives the source output enable signal SOE and the inversed source output enable signal /SOE. At this time, the second input unit 500 provided in the holding bit storage 325a is driven to receive the logic signal from the sampling bit storage 324a connected thereto. That is, when the source output enable signal SOE and the inversed source output enable signal /SOE are supplied, the fifth transistor M14 and the sixth transistor M15 connected in the transmission gate form are turned on, thereby supplying the logic signal from the first inverter 402 to the second capacitor C2. For example, when the first inverter 402 outputs the logic signal of “0”, the second capacitor C2 is charged with the voltage corresponding to the logic signal of “0”.

After charging the second capacitor C2 with the voltage corresponding to the logic signal of “0”, the source output enable signal SOE (i.e., the low level signal) is not supplied, so that the second input unit 500 stops operating. In addition, the second inverter 502 inverses the logic signal charged in the second capacitor C2 and supplies the inversed logic signal to the level shifter 326. For example, when the second capacitor C2 is charged with the voltage corresponding to the logic signal of “0”, the seventh transistor M16 is turned on, thereby supplying the logic signal of “1” to the level shifter 326. That is, when the sampling bit storage 324a receives the logic signal of “1”, the holding bit storage 325a supplies the logic signal of “1” to the level shifter 326.

In addition, the initialization signal INIT is supplied after the supplied of the source output enable signal SOE has stopped. When the initialization signal INIT is supplied, the second transistor M11 is turned on and the second voltage VSS is supplied to the first capacitor C1. Then, the voltage stored in the first capacitor C1 is initialized.

According to an embodiment of the present invention, each of the sampling bit storage 324a and the holding bit storage 325a includes four transistors and one capacitor. Thus, as compared with the conventional sampling bit storage and the conventional holding bit storage including ten or more transistors, the sampling bit storage 324a and the holding bit storage 325a can reduce a layout area thereof, and thus allow the transistors to be easily mounted on a panel. Further, the sampling bit storage 324a and the holding bit storage 325a charges the capacitors C1 and C2 with the voltage corresponding to the logic signal, thereby decreasing power consumption. In other words, the output is not fed back to the input as is in the conventional sampling and holding bit storages, so that power consumption is decreased.

FIG. 8 illustrates a sampling bit storage and a holding bit storage according to another embodiment of the present invention. Here, like numerals refer to like elements as compared with FIG. 6, and repetitive descriptions thereof will be avoided for convenience and/or ease of description purposes.

Referring to FIG. 8, a first input unit 401 of a sampling bit storage 324a′ includes a twentieth transistor M20 and a twenty first transistor M21 which are connected in the transmission gate form. The twentieth transistor M20 is implemented with a PMOS and is turned on when the sampling signal SP is supplied. The twenty first transistor M21 is implemented with an NMOS and is turned on when the inversed sampling signal /SP is supplied. As the twentieth transistor M20 and the twenty first transistor M21 are turned on, 1 bit of the data Data is supplied from the data supplying line L1 to the first capacitor C1. Then, the first capacitor C1 is charged with the voltage corresponding to the logic signal of 1 bit supplied thereto.

Thus, the sampling bit storage 324a′ according to this embodiment of the present invention has substantially the same configuration as the sampling bit storage 324a of FIG. 6 except for the first input unit 401, and is driven substantially the same as the sampling bit storage 324a of FIG. 6. However, when the first input unit 401 is connected in the transmission gate form, the initialization signal INIT shown in FIG. 7 can be omitted.

As described above, in a data driver according to an embodiment of the present invention and an organic light emitting display device using the same, each of a sampling bit storage and a holding bit storage includes a capacitor and uses it to store a digital value of data Data, so that the layout area is reduced. As each layout area of the sampling bit storage and the holding bit storage is reduced, the sampling latching part and the holding latching part can be easily mounted to a panel. Further, according to the present invention, the capacitor employed for storing the digital value of the data Data reduces power consumption because the output does not have to be fed back to the input.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

What is claimed is:

1. A data driver comprising:
a shift registering part adapted to supply sampling signals;
a sampling latching part comprising a plurality of sampling latches adapted to store data in response to the sampling signals; and
a holding latching part comprising a plurality of holding latches adapted to receive the data stored in the sampling latches in response to an externally supplied source output enable signal,
wherein each of the sampling latches comprises a plurality of sampling bit storages, each of the sampling bit storages comprising:
a first input unit adapted to receive a certain bit of the data;
a first capacitor adapted to store voltage corresponding to a logic signal of the certain bit supplied from the first input unit; and
a first inverter adapted to inverse the logic signal stored in the first capacitor.

2. The data driver according to claim 1, wherein the sampling bit storages comprise k sampling bit storages adapted to store data of k bits, and wherein k is a natural number.

3. The data driver according to claim 1, wherein the first input unit comprises:
a first transistor adapted to turn on when the sampling signal is supplied and to supply the certain bit to the first capacitor; and
a second transistor adapted to turn on when an initialization signal is supplied from an external source and to supply a certain voltage to initialize the first capacitor.

4. The data driver according to claim 1, wherein the first input unit comprises a first transistor and a second transistor, and wherein the first transistor and the second transistor are connected in a transmission gate form and supply the certain bit to the first capacitor when the sampling signal and an inversed sampling signal are supplied.

5. The data driver according to claim 1, wherein each of the holding latches comprises a plurality of holding bit storages adapted to store the data supplied from the sampling bit storages.

6. The data driver according to claim 5, wherein the holding bit storages comprises k holding bit storages adapted to store data of k bits, and wherein k is a natural number.

7. The data driver according to claim 5, wherein each of the holding bit storages comprises:
a second input unit adapted to receive the certain bit from the sampling bit storage connected thereto;
a second capacitor adapted to store voltage corresponding to the logic signal of the certain bit supplied from the second input unit; and
a second inverter adapted to inverse the logic signal stored in the second capacitor.

8. The data driver according to claim 7, wherein the second input unit comprises a first transistor and a second transistor, and wherein the first transistor and the second transistor are connected in a transmission gate form and supply the certain bit to the second capacitor when the source output enable signal and an inversed source output enable signal are input.

9. The data driver according to claim 1, further comprising:
a digital-analog converter adapted to receive the data stored in the holding latching part and to generate a data signal corresponding to a digital value of the received data; and
a buffering part adapted to supply the data signal to data lines.

10. The data driver according to claim 9, further comprising a level shifter provided between the digital-analog converter and the holding latching part, and adapted to boost up a voltage level of the data supplied from the holding latching part to the digital-analog converter.

11. An organic light emitting display device comprising:
a scan driver adapted to drive scan lines;
a data driver adapted to supply a data signal to data lines and comprising a plurality of sampling bit storages and a plurality of holding bit storages adapted to store a bit of the data; and
a display region comprising a plurality of pixels connected with the scan lines and the data lines and adapted to emit light corresponding to the data signal, wherein each of the sampling bit storages comprises:
a first input unit adapted to receive a certain bit of the data signal;
a first capacitor adapted to store voltage corresponding to a logic signal of the certain bit supplied from the first input unit; and
a first inverter adapted to inverse the logic signal stored in the first capacitor.

12. The organic light emitting display device according to claim 11, wherein the first input unit comprises:
a first transistor adapted to turn on when a sampling signal is supplied from a shift register provided in the data driver and to supply the certain bit to the first capacitor; and
a second transistor adapted to turn on when an initialization signal is supplied from an external source and to supply a certain voltage to initialize the first capacitor.

13. The organic light emitting display device according to claim 11, wherein the first input unit comprises a first transistor and a second transistor, and wherein the first transistor and the second transistor are connected in a transmission gate form and supply the certain bit to the first capacitor when a sampling signal and an inversed sampling signal are supplied from a shift register provided in the data driver.

14. The organic light emitting display device according to claim 11, wherein each of the holding bit storages comprises:
a second input unit adapted to receive the certain bit from the sampling bit storage connected thereto;
a second capacitor adapted to store voltage corresponding to a logic signal of the certain bit supplied from the second input unit; and
a second inverter adapted to inverse the logic signal stored in the second capacitor.

15. The organic light emitting display device according to claim 14, wherein the second input unit comprises a first transistor and a second transistor which are connected in a transmission gate form and supply the certain bit to the second. capacitor when a source output enable signal and an inversed source output enable signal are input from an external source.

16. The organic light emitting display device according to claim 11, wherein the data driver comprises:
a shift register adapted to supply sampling signals in sequence;
a plurality of sampling latches comprising k sampling bit storages adapted to store data of k bits when the sampling signals are supplied, wherein k is a natural number; and
a plurality of holding latches comprising k holding bit storages adapted to store the data in response to an externally supplied source output enable signal; and
a digital-analog converter adapted to receive the data stored in the holding latches and to generate a data signal corresponding to a digital value of the received data.

17. The organic light emitting display device according to claim 17, wherein the data driver comprises:
a level shifter provided between the digital-analog converter and the holding latches and adapted to boost up a voltage level of the data supplied from the holding latches to the digital-analog converter; and
a buffering part adapted to supply the data signal to the data lines.

18. A data driver comprising:
a shift registering part adapted to supply sampling signals;
a sampling latching part comprising a plurality of sampling latches adapted to store data in response to the sampling signals; and
a holding latching part comprising a plurality of holding latches adapted to receive the data stored in the sampling latches in response to an externally supplied source output enable signal,
wherein each of the holding latches comprises a plurality of holding bit storages, each of the holding bit storages comprising:
a first input unit adapted to receive a certain bit of the data;
a first capacitor adapted to store voltage corresponding to a logic signal of the certain bit supplied from the first input unit; and
a first inverter adapted to inverse the logic signal stored in the first capacitor.

19. The data driver according to claim 18, wherein each of the sampling latches comprises a plurality of sampling bit storages adapted to supply the data to the holding bit storages.

20. The data driver according to claim 18, wherein the first input unit comprises a first transistor and a second transistor, and wherein the first transistor and the second transistor are connected in a transmission gate form and supply the certain bit to the second capacitor when the source output enable signal and an inversed source output enable signal are input.
